(19) United States
(12) Patent Application Publication
(10) Pub. No.: US 2003/0117543 A1
(43) Pub. Date: Jun. 26, 2003

(54) Structure of a display device

(76) Inventor: Ching-Yun Chang, Taichung Hsien (TW)

Correspondence Address: SUPREME PATENT SERVICES, POST OFFICE BOX 2339, SARATOGA, CA, 95070, US

(21) Appl. No.: 10/027,306

(22) Filed: Dec. 21, 2001

(51) Int. Cl. G02F 1/1333; G02F 1/1345

(52) U.S. Cl. 349/58; 349/56; 349/84

(57) ABSTRACT

A structure of a display device comprises an organic luminescent diode display faceplate, a flexible PCB, a driving IC element, a conductive adhesive, and a passive element for driving the resistance capacitance of the circuit. The organic luminescent diode display faceplate is mounted with the faceplate electrodes (anode and cathode). The flexible PCB is mounted on the center rear end of the organic luminescent diode display faceplate. The outside of the flexible PCB is mounted with a plurality of outer lead bonding; and the inside of the flexible PCB is mounted with a plurality of inner lead bonding. The conductive adhesive is connected between the faceplate electrodes of the organic luminescent diode display faceplate and the outer lead bonding on the outside of the flexible PCB, and also between the inner lead bonding inside the flexible PCB and the driving IC element, thereby making the display device light, thin, artful and small

### FIELD OF THE INVENTION

The present invention relates to a structure of a display device, particularly a construction for an organic luminescent diode faceplate or a liquid crystal faceplate. The present invention uses a better technology to combine an organic luminescent diode or a liquid crystal faceplate with a preferred modular construction in conformance with the structure, thereby developing another new modular structure.

### BACKGROUND OF THE INVENTION

Since the publication of the researches on the small molecular and macromolecular organic luminescent diodes by the Eastman Kodak in the U.S.A. in 1987 and the Cambridge University in the Great Britain in 1990, the organic luminescent diodes, with their advantages of self-luminescence, wide view angle, high resolution, high brightness, and rapid response speed, etc., are deemed as the new application technology for the flat display of the next generation. Therefore, many companies and research organizations around the world are actively involved in the research and development of the technology.

From the point of view of commercial applications, in addition to the requirements of the process, cost and characteristics, the flat display, that is light, thin, artful and small, has met the ideal and basic requirements in comparison with the modern electronic products. Therefore, in addition to looking for a breakthrough in the production process, researchers are looking for miniaturization and simplification in layers with regard to the construction. As a result, the technology disclosed in the present invention is derived from such an environment. In addition to using a preferred structure of an organic luminescent diode, the present invention further combines a preferred modular construction in conformance with such a structure, and develops a novel modular structure that can not be reached by a conventional technique. The technology according to the present invention, when applied to a display module, will enable the display reaching an ideal state of light, thin, artful and small.

Presently, the organic luminescent diode display modular construction mainly follows the construction technology of a liquid crystal display. However, there are many patents available worldwide with regard to the display devices. For example, U.S. Pat. No. 4,862,153 “FALT DISPLAY PANEL WITH FRAMING FOR FLEXIBLE SUBSTRATE FOLDING” disclosed that: each flexible wiring substrate (including LSI) was connected to a PCB from the upper and lower glass of a LCD through an S-shaped folding. U.S. Pat. No. 5,341,233 “LIQUID CRYSTAL MODULE WITH TAB ASSEMBLIES CONNECTED THROUGH A FLEXIBLE CIRCUIT BOARD” disclosed that: each TAB-LSI, below a LCD, was connected to a flexible PCB through the I/O terminals of the upper and lower glass. U.S. Pat. No. 4,655,551 “LIQUID CRYSTAL DISPLAY WITH CHIP PROJECTING ABOVE AND BELOW FLEXIBLE FILM” disclosed that: each flexible wiring film (including LSI), below a LCD, was connected a PCB through the I/O terminals of an upper glass. Japan Patent No. 03204619A2 “LIQUID CRYSTALDISPLAY DEVICE” disclosed that: each COF was connected in parallel to a PCB through the I/O terminals of the upper and lower glass of a LCD. Japan Patent No. 02137822A2 “LIQUID CRYSTAL DISPLAY DEVICE” disclosed that: each COF was connected in parallel to a PCB through the I/O terminals of the upper and lower glass of a LCD. Japan Patent No. 04218933A2 “FLEXIBLE CIRCUIT BOARD AND LIQUID CRYSTAL DISPLAY DEVICE” disclosed that: each COF was connected in parallel to a PCB through the I/O terminals of the upper and lower glass of a LCD.

Furthermore, Taiwan Patent Publication No. 392139 “A Display Device” disclosed that: a terminal of a display element, formed by a transparent substrate and a liquid crystal sandwiched therebetween, was connected to a terminal portion of a film plate; which was characterized in that: the film plate was located on the inner side of the display element, and the terminal portion of the film plate comprises folding back a spacer sandwiched therebetween and connecting to the terminals of the display element; wherein the terminals of the display element were installed on a plurality of adjacent side faces of one of the transparent substrates, and the terminal portion of the film plate was connected to the plurality of side faces; wherein a slit produced in the film plate was used to form another I/F terminal.

The display device has a number of drawbacks. For example, a spacer is used to fold back the film plate. The production of such a spacer or the use of such a space for folding back is liable to increase the cost and the complexity of the process, which requires improvement. Furthermore, the whole structure is complicated and is liable to increase the volume and weight of the device. This is not suitable for a portable communication product in the future that needs to be light, thin, short, and small.

As shown in FIG. 1, a schematic diagram of the structure of a conventional modular construction indicates the following drawbacks of a modular construction technology. Presently, a conventional modular construction adopts a connector, such as a flexible PCB, a thermocompression paper, a metal pin, or a conductive rubber, etc., to connect an electrode with a circuit board. If the electrode is mounted on a plurality of sides, the number of connector needed will increase correspondingly. A circuit board carries driving circuits and elements. The processor, which controls such driving circuits, is connected through another connector. The use of many types of material increases the cost, as well as the complexities of the construction layering and the process. A LCM construction technique has the following major drawbacks:

1. A surface mounting technique (SMT) can not meet the demand of a small clearance. Furthermore, the minimum thickness of a PCB is about 0.4 mm. As a result, the whole construction is too heavy.

2. When a tape automated bonding (TAB) technique is applied on the bonding at a small clearance, the thermal expansion characteristics of the tape needs to be taken into consideration. The directions of the signal I/O are fixed. Furthermore, a passive element needs to be attached to another substrate and has a poorer flexibility.

3. In a chip-on-glass (COG) technique, a passive element needs to be attached to another substrate. Furthermore, a signal attenuation or a crosstalk is likely to occur due to an excessive impedance on the indium tin oxide electrode.

4. A chip-on-film (COF) technique comprises turning a bare chip in order to combine an IC with a flexible circuit board. A passive element can be directly carried on a flexible circuit board. This technique can design the positions of signal I/O according to the requirements of a product, and has a high flexibility with a thickness about ⅛ of a PCB, or ⅓ of a TAB.

By using a COF LCM construction technique, the scanning electrode and the display electrode of an ordinary liquid crystal display with a small size are on one side of a same glass of a faceplate. This increases the length of wiring for the scanning (or display) electrode, thereby increasing the impedance thereof and causing the formation of crosstalk. For a medium- or large-sized liquid crystal display, the scanning electrode and the display electrode are mounted on the upper and lower glass of the faceplate; in its modular construction, however, similar to a TAB, the electrodes on the faceplate are connected to several COF. The signal input terminals of these COF are connected to a circuit board having a driving circuit thereon. This increases a lot of process steps.

Therefore, by reviewing the known drawbacks in the conventional techniques, the inventors of the present invention developed a novel technique after many researches and experiments.

A novel structure of a display device according to the present invention uses a COF construction technique, and can be used in the construction technique of an organic luminescent diode display device or a liquid crystal display device. Such that an organic luminescent diode display device or a liquid crystal display device can achieve the objectives of being lighter, thinner, shorter and smaller. Furthermore, the present invention, particularly when applying to an organic luminescent diode or a liquid crystal display device, has the following advantages:

1. The present invention, when applied to an organic luminescent diode or a liquid crystal display device, also meets the characteristics of a display in a multimedia era. These characteristics are no viewing angle, simple process, low cost, high response speed, power saving, wide range of application temperature, full color, etc.

2. When used in an organic luminescent diode display, the electrodes (anode and cathode) according to the present invention are often mounted on the two sides (or more than two sides) of the faceplate. Many connection devices are needed to connect the electrodes on the faceplate. By using the present invention, a single device can be used to connect all electrodes and a design according to the present invention uses the least amount of material.

3. According to the present invention, a flexible PCB also comprises the functions of a connector, a driving circuit board, etc. With a thin film thickness, the weight and volume of the product can be reduced and the flexibility can be increased. An IC and a passive element can be mounted on the back of a display faceplate, thereby reducing the front area of the product, making a luminescent display more applicable on 3C electronic products, such as a portable communication device, etc.

4. When used in an organic diode display, the electrodes (anode and cathode) of the faceplate according to the present invention can be drawn linearly. Depending on the requirements of combining with a circuit board, the wire diameter of the pin drawn from the electrodes of the faceplate can be enlarged or reduced. However, the pitch remains the same as the pixel. This can simplify the design and reduce the impedance of an electrode to a minimum, thereby reducing the power consumption.

5. According to the present invention, the edge size of the whole module is the smallest. The edge size is identical to the faceplate size. The edge size of an ordinary display will be larger than the faceplate, in some cases, even to a large extent.

6. When applied to an organic luminescent diode, the present invention has the characteristics of lowering the operation voltage and the operation power of the display.

### SUMMARY OF THE INVENTION

The main objective of the present invention is to provide a structure of a display device, wherein the display device comprises a faceplate electrode on an organic luminescent diode or a liquid crystal display faceplate, such that a flexible PCB, after mounted with a driving IC element and a passive element, can be attached to a plurality of pins on the faceplate electrode at the lower end of the faceplate, thereby reducing the production steps, labor cost, contamination in the material process, as well as increasing the yield during the assembly process, while avoiding the poor result where the solder terminal is liable to break during the production process when a TCP is used.

Another objective of the present invention is to provide a structure of a display device, wherein a flexible PCB is mounted on the center rear end of an organic luminescent diode display faceplate, wherein the outside of the circuit board is mounted with a plurality of external pins which can combine with the faceplate electrode of the organic luminescent diode display faceplate, the interior of which being mounted with a plurality of internal pins which can combine with a driving IC element. Since the thickness of the flexible film is small, the product has a reduced weight and volume, as well as a good flexibility. Therefore, the driving IC element and the passive element can be folded to the back of the organic luminescent diode display faceplate, thereby reducing the external area of the product and making it more suitable for portable communication electronic products.

Another objective of the present invention is to provide a structure of a display device, wherein a driving IC is mounted with a plurality of metal bump pins, such that the driving IC element combines with the inner lead bonding inside a flexible PCB through a conductive adhesive. Therefore, all signal I/O of the driving IC element can be combined with the flexible PCB through one production step, thereby simplifying the production of the display device, and reducing the production steps, labor cost and contamination in the material process.

In order to achieve the abovementioned objectives, the present invention provides a structure of a display device, which comprises:

a display faceplate mounted with a glass faceplate, wherein the glass faceplate is mounted with a faceplate electrode, the faceplate electrode being mounted with a plurality of pins;

a flexible PCB mounted on the center rear end of the display faceplate, the flexible PCB being mounted with an inner lead bonding capable of combining with a plurality of driving IC elements, a plurality of outer lead bonding connected to the faceplate electrode, and a plurality of passive elements, one side of the flexible PCB being mounted with at least one connection device of a signal input end;

a plurality of driving integrated circuits, the driving IC chip being mounted with a plurality of metal bump pins, so that the driving IC element combines with the inner lead bonding inside the flexible PCB; and

a conductive adhesive connected to the display faceplate electrode and the flexible PCB; the conductive adhesive also being connected to the metal bump pins of the IC element and the inner lead bonding of the flexible PCB.

### BRIEF DESCRIPTION OF THE DRAWINGS

FIG. 1 shows the top view and the side view of the schematic structure of a conventional display device;

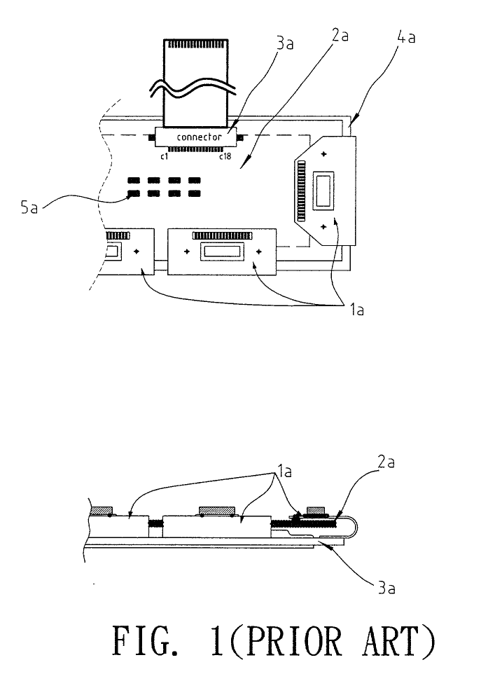

FIG. 2 shows a 3-D structure diagram of a first example according to the present invention;

FIG. 3 shows a 3-D structure diagram of a second example according to the present invention;

FIG. 4 shows a side view of a structure of the first example according to the present invention;

FIG. 5 shows another side view of a structure of the second example according to the present invention; and

FIG. 6 shows another side view of a structure of the second example according to the present invention.

### DETAILED DESCRIPTION OF THE INVENTION

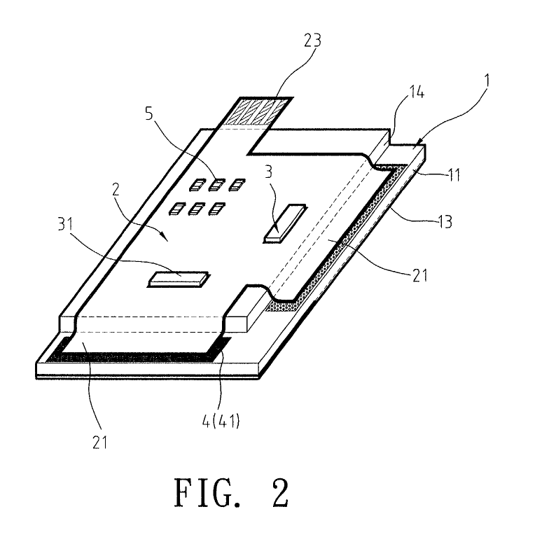

FIG. 2 to FIG. 6 show the 3-D structure back view, the side view of a first example of the present invention, and the 3-D structure back view of a second example of the present invention. The present invention provides a display device, which comprises an organic luminescent diode or a liquid crystal display faceplate 1, a flexible PCB 2, a driving IC element 3, a conductive adhesive 4, and a passive element 5.

The display faceplate 1 is mounted with an upper glass faceplate 11 and a plurality of pin faceplate electrodes 12 mounted thereon, a polarizer 13 being installed below the glass faceplate 11, a sealing cap 14 being mounted on the glass faceplate 11 (as shown in FIG. 2), wherein the display faceplate can be an organic luminescent diode faceplate or a liquid crystal faceplate.

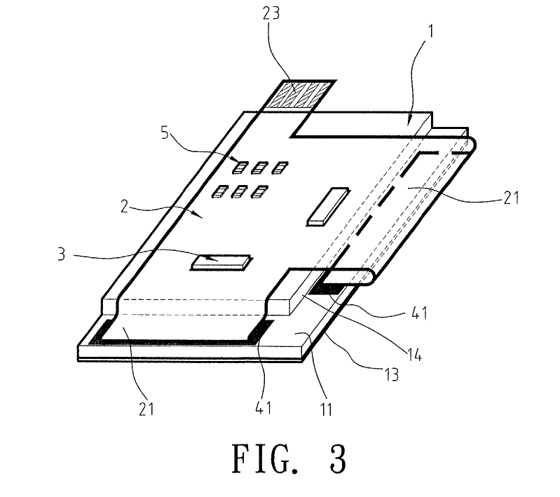

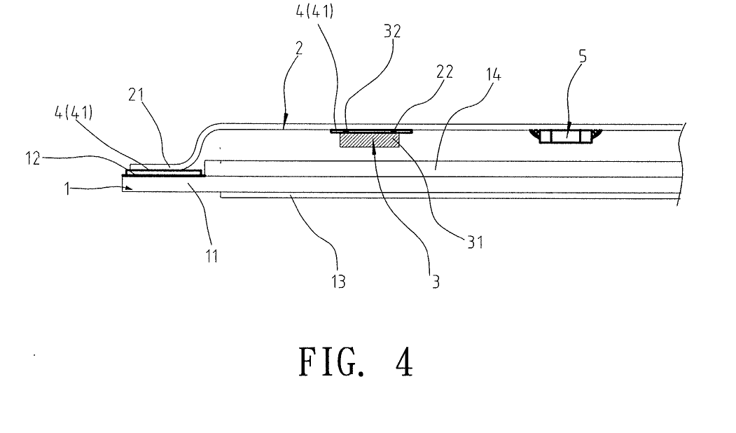

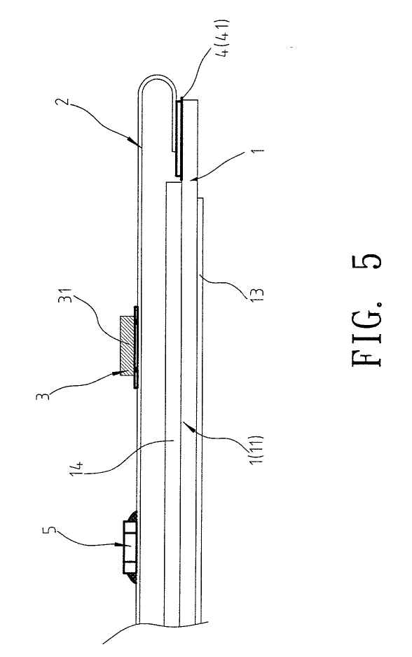

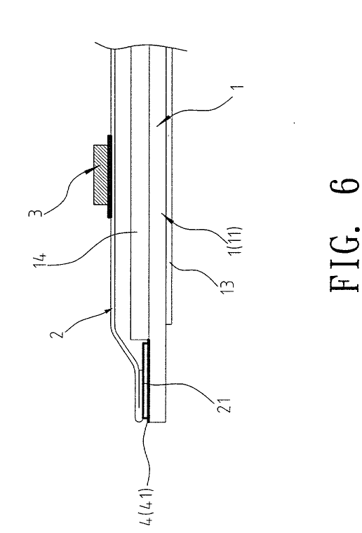

The flexible PCB 2 is mounted on the center rear end of the display faceplate 1, the lower end or the upper end of which capable of carrying a plurality of driving IC elements 3 and passive elements 5. The outside of the flexible PCB 2 is installed with a plurality of outer lead bonding 21 which can combine with the faceplate electrode 12 of the display faceplate 1, the interior of which being installed with a plurality of inner lead bonding 22 which can combine with the driving IC elements 3. Furthermore, one side of the flexible PCB 2 is mounted with at least one signal input end 23, which can control the driving IC elements 3 by connecting to a processor (as shown in FIG. 3).

Wherein the plurality of outer lead bonding 21 (OLB) of the flexible PCB 2 can directly combine with the faceplate electrode 12 of the display faceplate 1 (as shown in FIG. 2 and FIG. 4). Alternatively, a plurality of outer lead bonding 21 (OLB) on one side can combine with the faceplate electrode 12 of the display faceplate 1 first (as shown in FIG. 5), and then be folded for 180 degrees at an R angle; while the plurality of outer lead bonding 21 on the other side is folded for 180 degrees and fixed prior to being combined with the display faceplate 1 (as shown in FIG. 6).

The driving IC element 3 is mounted with a plurality of metal bump pins 32, such that the driving IC element 3 combines with the inner lead bonding 22 inside the flexible PCB 2 by the conductive adhesive 4 (as shown in FIG. 4, FIG. 5 and FIG. 6).

The conductive adhesive 4 can be an anisotropic conductive adhesive 41, which is adhered between the faceplate electrode 12 of the glass faceplate 11 of the display faceplate 1 and the outer lead bonding 21 of the flexible PCB 2, and between the driving IC element 3 and the flexible PCB 2.

The passive element 5 is mounted on the flexible PCB 2 for driving the circuit.

Thus, the structure of a display device can be applied on an ordinary small-sized portable display structure, thereby making the product light, thin, artful and small, while reducing the consumption of material.

Therefore, a structure of a display device according to the present invention can achieve the desired objectives and performance, and meet the novelty, improvements and industrial application requirements of a patent.

However, the abovementioned drawings and explanation are for the preferred examples of the present invention only, and are not used to limit the present invention. A person skilled in the art can vary or modify the present invention without departure from the scope of the present invention, which is defined in the following claims.

What is claimed is:

1. A structure of a display device, which comprises:
a display faceplate mounted with a glass faceplate, wherein said glass faceplate is mounted with a faceplate electrode which is mounted with a plurality of pins;
a flexible PCB mounted on the center rear end of said display faceplate, and capable of being mounted with inner lead bonding connected with a plurality of driving IC elements, a plurality of outer lead bonding connected to the faceplate electrode, and a plurality of passive elements; one side of said flexible PCB being mounted with at least a connection device of a signal input end;
a plurality of driving integrated circuits, said driving IC chip being mounted with a plurality of metal bump pins such that said driving IC element combines with the inner lead bonding inside said flexible PCB;
a conductive adhesive connected to said display faceplate electrode and said flexible PCB; said conductive adhesive also being connected to said metal bump lead of said IC element and said inner lead bonding of said flexible PCB.

2. The structure as claimed in claim 1, wherein said display faceplate is an organic luminescent diode faceplate or a liquid crystal faceplate.

3. The structure as claimed in claim 1, wherein a plurality of outer lead bonding are mounted on the two sides of said flexible PCB, the outer lead bonding on one side of said flexible PCB being folded for 180 degrees and fixed prior to being combined with said display faceplate; after a plurality of outer lead bonding on the other side being combined with the faceplate electrode of said display faceplate, said flexible PCB is folded for 180 degrees by an R angle to the back of the faceplate; then, the plurality of outer lead bonding on this side (being folded for 180 degrees and fixed) are combined with the faceplate electrode of said display faceplate.

4. The structure as claimed in claim 2, wherein said flexible PCB is directly combined with said faceplate electrode by said conductive adhesive without any folding treatment.

5. The structure as claimed in claim 1, wherein said conductive adhesive is a paste-like or film-like thermoplastic or thermoset or UV-curable connection material.

6. The structure as claimed in claim 1, wherein said glass faceplate is a plastic faceplate or any other flexible faceplate material.

7. The structure as claimed in claim 1, wherein said driving IC chip is a surface mount encapsulated QFP, COB, SOP, TSOP, SSOP.
